(19) United States
(12) Patent Application Publication
(10) Pub. No.: US 2005/0264178 A1
(43) Pub. Date: Dec. 1, 2005

(54) Organic electroluminescent device and method for manufacturing the same

(76) Inventors: Wen-Jeng Lan, Chu-Nan (TW); Chin Chung Chang Chien, Chu-Nan (TW); Hui Chang Yu, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/134,402

(22) Filed: May 23, 2005

(30) Foreign Application Priority Data
May 25, 2004 (TW) 093114841

(51) Int. Cl. H05B 33/00; H05B 33/10

(52) U.S. Cl. 313/503; 313/504; 313/506

(57) ABSTRACT

An organic electroluminescent device comprises a substrate; a black matrix pattern layer deposited on the substrate as a predetermined pattern; a passivation layer laying over the substrate and the black matrix pattern layer; an anode pattern layer deposited on the passivation as a predetermined pattern; a luminescent layer structure deposited on the anode pattern layer; and an isolation area being an isolation between the anode pattern layer. Among them, the black matrix pattern layer has low reflectivity, and the black matrix pattern layer has a first matrix pattern corresponding to the isolation area or further comprises a second matrix pattern corresponding to the anode pattern layer.

### FIELD OF THE INVENTION

The present invention is related to an organic light emitting diode, and more particularly to an organic light emitting diode with light emitting area with bounded pixels and improved light emitting efficiency and enhanced light source contrast effect.

### BACKGROUND

Please refer to FIG. 1, a cross section view of a prior art organic light emitting diode element 10. The organic light emitting diode element 10 mainly comprises a substrate 100, an anode pattern layer 120 formed a predetermined pattern on the substrate 100, a luminescent layer structure 140 mainly on the anode pattern layer 120, a cathode layer 122 on the luminescent layer structure 140, and an isolation area 160 in the anode pattern layer 120 as an isolation. Among them, the luminescent layer structure 140 comprises HTL 142, EML 144, and ETL 146 in an order from bottom to top. After the current is passed through the anode pattern layer 120 and the cathode layer 122, electronic hole combines and emits light at the EML 144 through the ETL 146 and HTL 142. To define a pixel measure of area and avoid a short circuit problem between each pixel (bounded by the anode pattern layer 120), the isolation area 160 is formed between the anode pattern layer 120.

The manufacturing steps of the prior art organic light emitting diode element 10 comprise: placing a substrate 100 and using surface active agents (chemical such as detergent, etc.) and deionized water to wash the substrate 100; using sputter to grow an ITO membrane 120 as an anode; make patterns on the ITO membrane 120 by a lithographic etching process; coating a photoresist, such as a material of polyimide; and making an isolation area 160 by a lithography process. Grow HTL 142, EML 144, ETL 146, and cathode layer 122, respectively, by a evaporating process.

However, in the prior art technology, when light emitted from different EML or external light enters the prior art organic light emitting diode element 10, it is easily affected each other. The resolution ability cannot be improved, and an effect of having light emitting area with bounded pixels and reducing mutual interference between EML with different colors at the same time cannot be achieved.

Therefore, the inventor researched and made use of theories to provide the present invention with reasonable design and widely and effectively improving the previous shortcomings with respect to the previous shortcomings.

### SUMMARY OF THE INVENTION

It is a primary object of the present invention to provide an organic light emitting diode element and a manufacturing method thereof which can have light emitting area with bounded pixels and reduce interference of external light source to improve light emitting efficiency, enhance grayscale and contrast effect to improve resolution ability and avoid from additional cost of adding a polarizer.

To achieve the previous mentioned object, the present invention provides an organic electroluminescent device comprises a substrate; a black matrix pattern layer deposited on the substrate as a predetermined pattern; a protection layer laying over the substrate and the black matrix pattern layer; an anode pattern layer deposited on the protection as a predetermined pattern; a luminescent layer structure deposited on the anode pattern layer; and an isolation area being an isolation between the anode pattern layer. Among them, the black matrix pattern layer has low reflectivity, and the black matrix pattern layer has a first matrix pattern corresponding to the isolation area.

To achieve the previous mentioned object, the present invention provides a method of manufacturing an organic electroluminescent device comprises: (a) placing a substrate and growing a black matrix film; (b) making a black matrix pattern by a lithographic etching process; (c) growing a passivation layer on the structure; (d) growing an anode film on the passivation layer; (e) making an anode pattern by a lithographic etching process; (f) coating a photoresist material and making an isolation area by a lithography process; and (g) making a luminescent layer structure. The black matrix pattern is used to bound light emitting area of pixels to reduce the interference of external light source and improve resolution ability.

The structural features and the effects to be achieved may further be understood and appreciated by reference to the presently preferred embodiments together with the detailed description.

### BRIEF DESCRIPTION OF DRAWINGS

FIG. 1 is a cross section view of a prior art organic light emitting diode element;

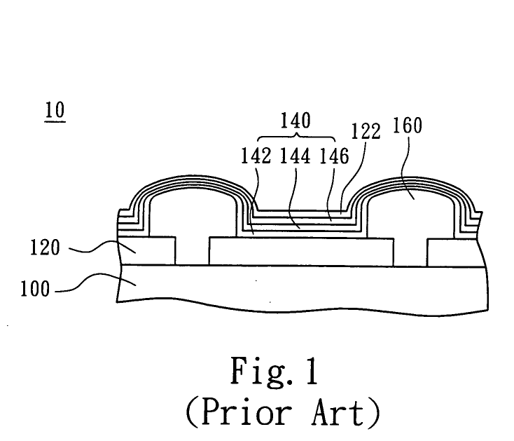

FIG. 2 is a cross section view of a first embodiment of the present invention;

FIG. 3 is a cross section view of a second embodiment of the present invention;

FIG. 4 is a top view of the second embodiment of the present invention;

FIG. 5 is a cross section view of a third embodiment of the present invention;

FIG. 6 is a cross section view of a fourth embodiment of the present invention;

FIG. 7 is a top view of the fourth embodiment of the present invention;

FIG. 8 is a cross section view of a fifth embodiment of the present invention;

FIG. 9 is a top view of the fifth embodiment of the present invention;

FIG. 10A to FIG. 10I are flow charts of the second embodiment of the present invention;

FIG. 11A to FIG. 11I are flow charts of the third embodiment of the present invention; and

FIG. 12A to FIG. 12B are cutaway views of a sixth embodiment of the present invention.

### DETAILED DESCRIPTION

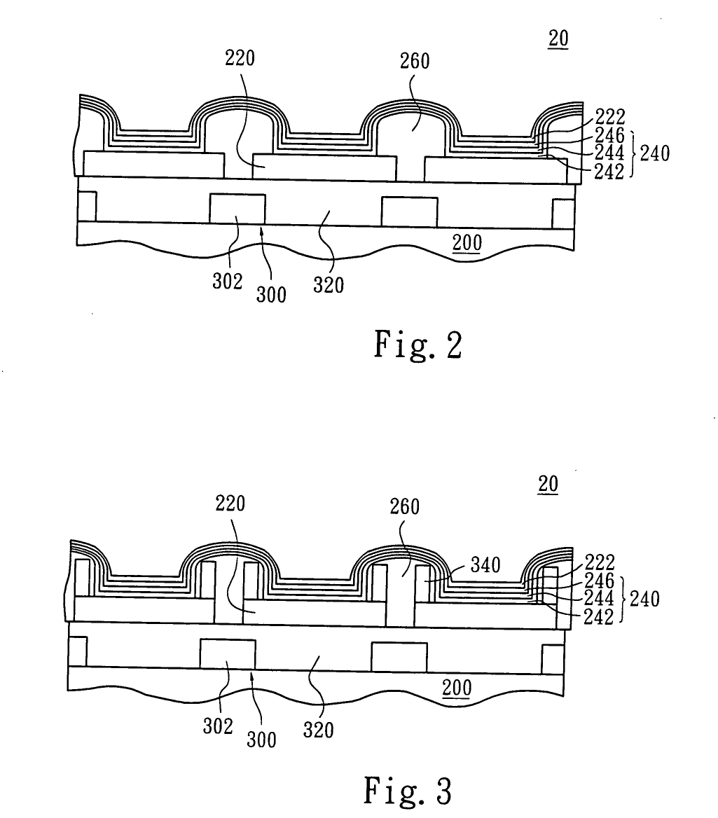

Please refer to FIG. 2, a first embodiment of an organic light emitting diode (OLED) element 20 of the present invention which comprises a substrate 200, a black matrix pattern layer 300 deposited on the substrate 200 as a predetermined pattern, a protection layer 320 laying over on the substrate 200 and the black matrix pattern layer 300, an anode pattern layer 220 deposited on the passivation layer 320 as a predetermined pattern, a luminescent layer structure 240 deposited on the anode pattern layer 220, and an isolation area 260 being between the anode pattern layer 220 as an isolation. Among them, the black matrix pattern layer 300 has low reflectivity, and the black matrix pattern layer 300 has a first matrix pattern 302 corresponding to the isolation area 260. Among them, the luminescent layer structure 240 comprises HTL 242, EML 244, and ETL 246 in an order from bottom to top. After the current is passed into the anode pattern layer 220 and the cathode layer 222, the electronic hole combines and emits light at the EML 244 through ETL 246 and HTL 242, wherein the luminescent layer structure 240 can be monochrome or polychrome. To define the pixel measure of area and avoid the problem of short circuit between each pixel (bounded by the anode pattern layer 220), the isolation area 260 is formed between the anode pattern layer 220 (ITO material). Among them, the first matrix pattern 302 can be used to define light emitting area of visible pixels whose function is not only avoiding the organic light source from overflowing to non-display area in the surroundings, but also the first matrix pattern 302 distributed around the pixels can reduce the reflective interference to the OLED element 20 from external light source.

Among them, the black matrix pattern layer 300 is consisted of materials of metallic oxide, such as chromium oxide, polyimide, sensitization acrylate, non-electrolytic/electroplating nickel, or graphite. The consisted materials of the protection layer 320 generally comprise using resin or epoxy resin as a foundation; using silicon oxide or silicon oxide nitride as a foundation; using polyimide or acrylic as a foundation; or applying polyimide or acrylic first, then growing on silicon oxide or silicon oxide nitride membrane on the foundations.

Further, the luminescent layer structure 204 can be selected as a structure layer capable of emitting light with different colors to become an organic light emitting element 20 of a three color independent light emitting structure (ex: in side by side evaporation process). For example, the luminescent layer structure 204 can be selected as a first light emitting structure layer, second light emitting structure layer, and third light emitting structure layer capable of emitting red light source, green light source, and blue light source, respectively. By combining various light sources, an object of fully colorfully displaying the organic light emitting element 20 can be achieved.

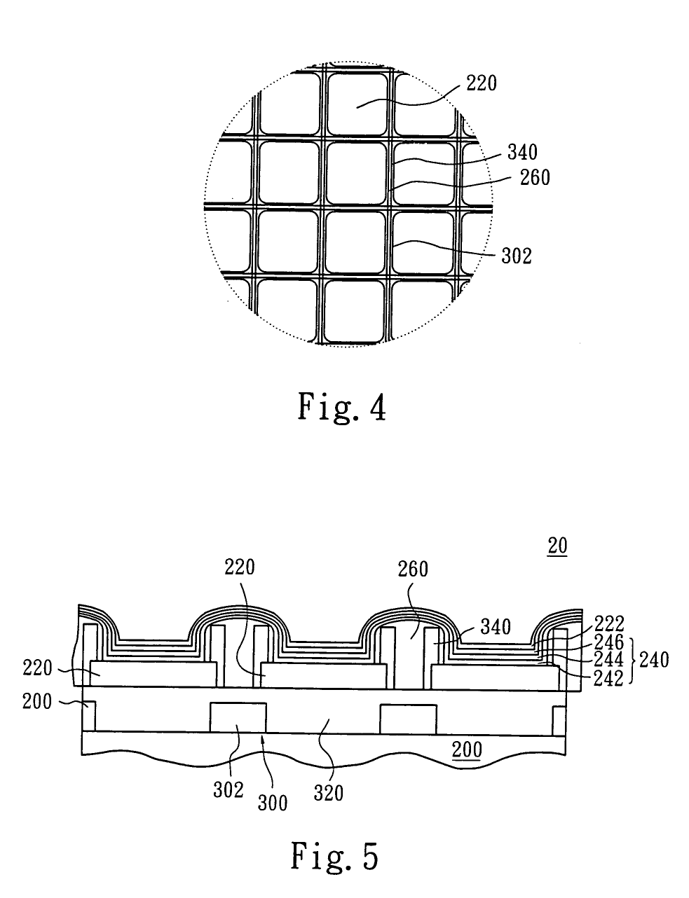

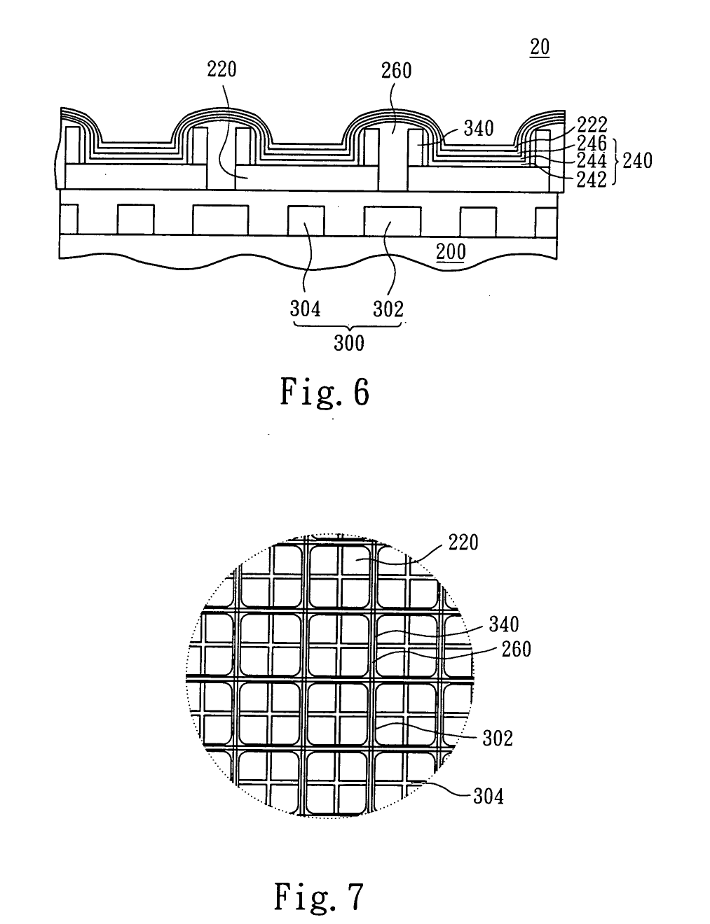

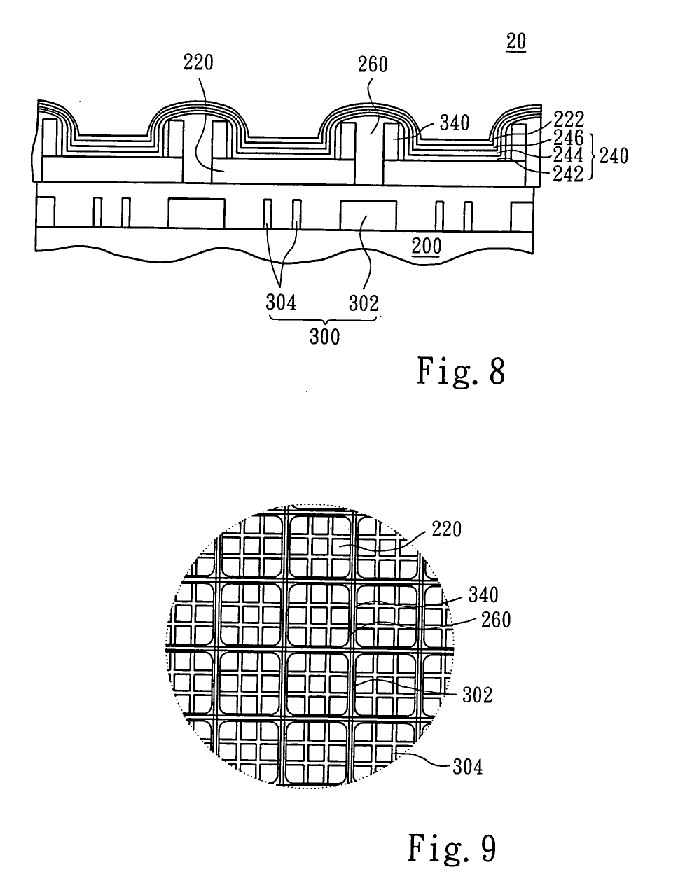

Please refer to FIG. 3 and FIG. 4, a second embodiment of the present invention. The organic light emitting diode element 20 further comprises a metallic matrix pattern 340 deposited around the anode pattern layer 220. Therefore, the metallic matrix pattern 340 distributed around the pixels can be used to define light emitting area of visible pixels. According to the embodiment, light with different EL colors can be avoided from interfering with each other, and further external light can be avoided from entering into the organic plane light emitting display. As shown in FIG. 3, the metallic matrix pattern 340 is on the edge of the anode pattern layer 220; the metallic matrix pattern 340 is at the side edge (not shown) of the anode pattern layer 220; or the metallic matrix pattern 340 is at the edge of the anode pattern layer 220 and covers the upper edge and side edge (please refer to FIG. 5) of the anode pattern layer 220. The metallic matrix pattern can be made from a material with high conductivity and reflectivity, such as gold, silver, aluminum, copper, and chromium.

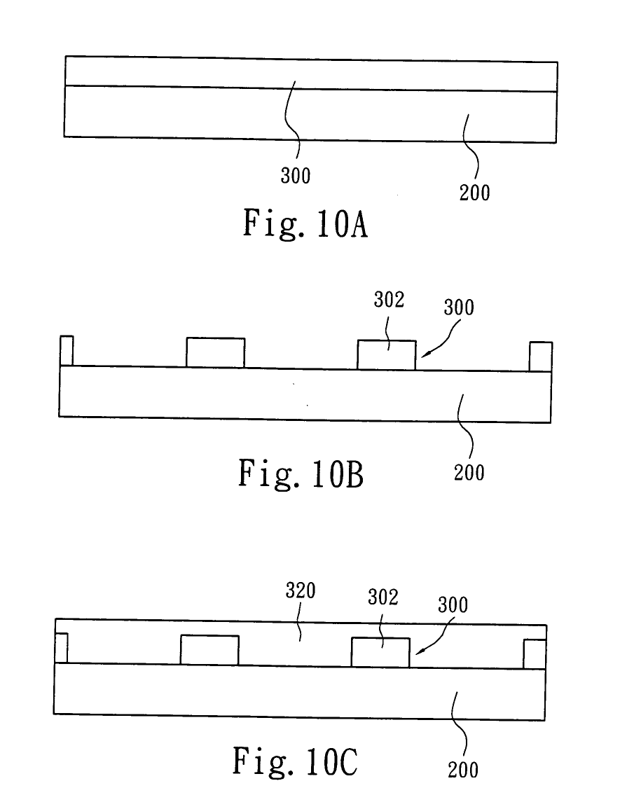

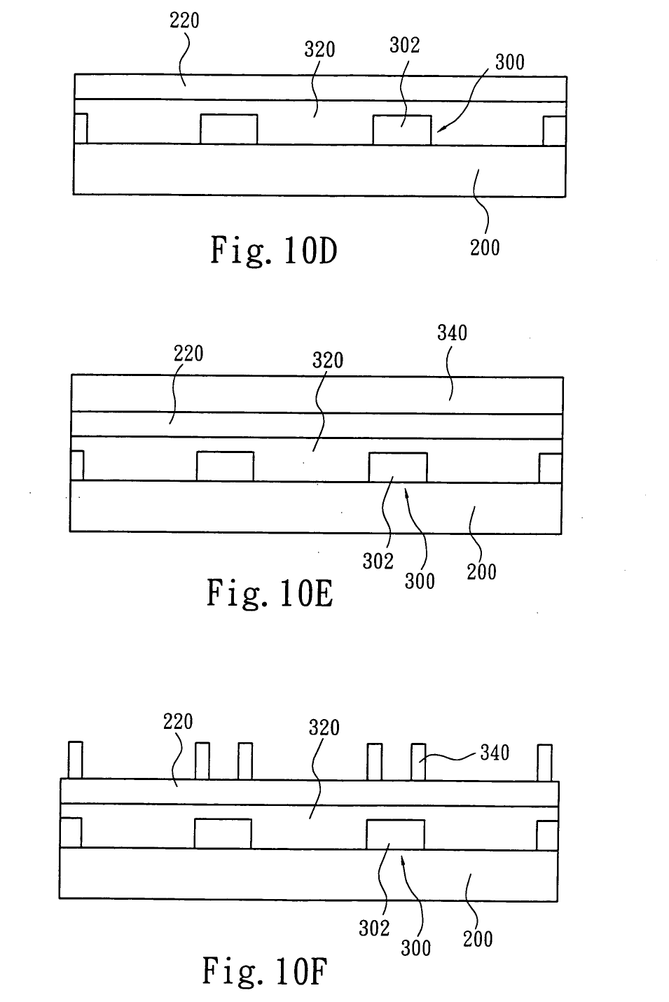

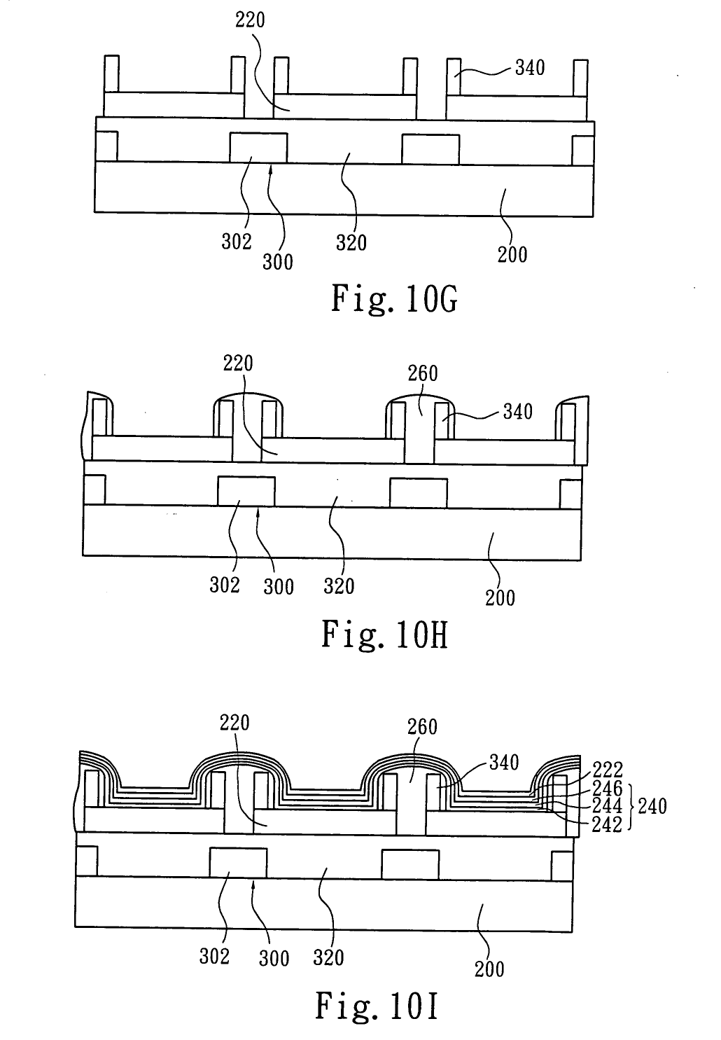

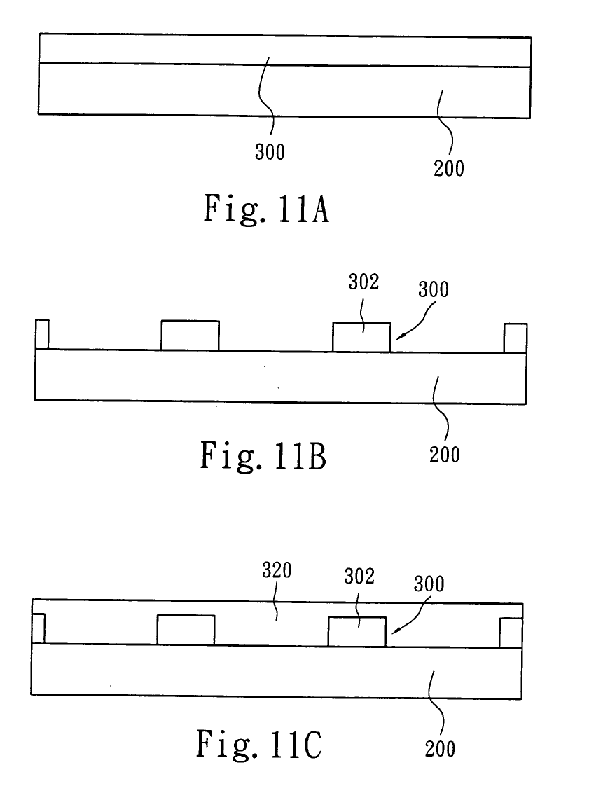

Please refer to FIG. 6 to FIG. 9, the black matrix pattern layer 300 further comprises a second matrix pattern 304. The second matrix pattern 304 is set on the substrate 200 apart from the first matrix pattern 302, and the second matrix pattern 304 corresponds to the anode pattern layer 220. In other words, the second matrix pattern 304 further limits the organic light source to overflow to the circumference and further reduces the external light source reflectively interfering with the OLED element 20 simultaneously. Therefore, the second matrix pattern 304 can provide higher resolution ability of the OLED element 20. As shown in FIG. 6 and FIG. 7, the second matrix pattern 304 is in a chunk and divides the light emitting area into two. As shown in FIG. 8 and FIG. 9, the second matrix pattern 304 is shown as two partitions and divides the light emitting area into plurality to reduce the effect caused by external light source entering the OLED element 20 and reflecting.

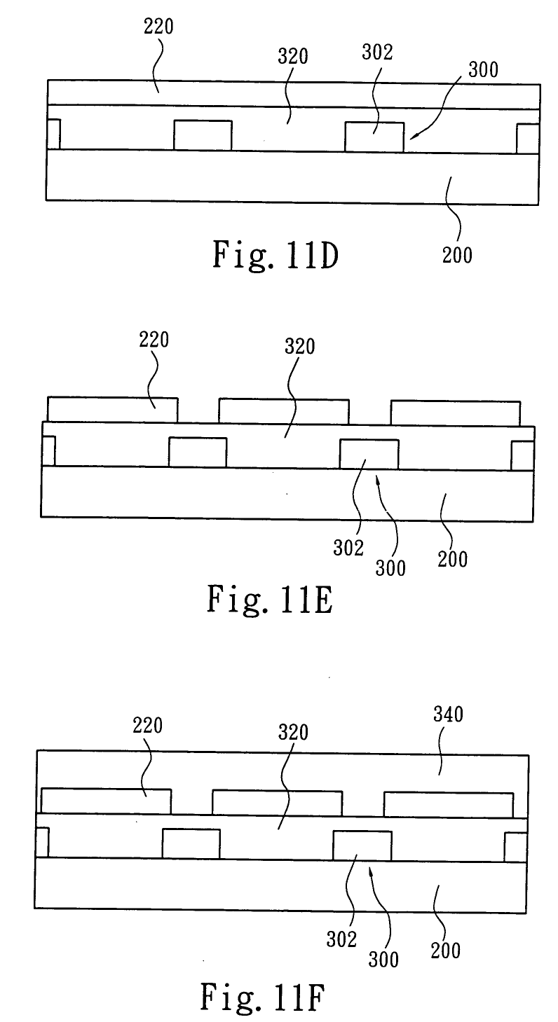

Please refer to FIG. 10A to FIG. 10I, manufacturing flow charts in accordance with the second embodiment of the present invention which comprises the following steps: (a) placing a substrate 200 and using chemical, such as detergent, and deionized water to wash the substrate 200, and then using sputter machine to grow a black matrix film 300, such as chromium oxide etc or coating black resin; (b) making the black matrix pattern 300 by a lithographic etching process; (c) applying polyimide or acrylic on the structure, and then growing a protection layer 320, such as silicon oxide or silicon oxide nitride film, by a chemical vapor deposit (CVD) process; (d) growing ITO membrane 220 to be an anode on the passivation layer 320; (e) using a sputter or electroplating machine to grow a metallic membrane 340; (f) making the metallic matrix pattern 340 by a lithographic etching process; (g) making the anode pattern 220 by a lithographic etching process; (h) coating photoresist material and making an isolation area 260 by lithography process; and (i) growing HTML 242, EML 244, ETL 246, and cathode layer 222, respectively, by a evaporating process.

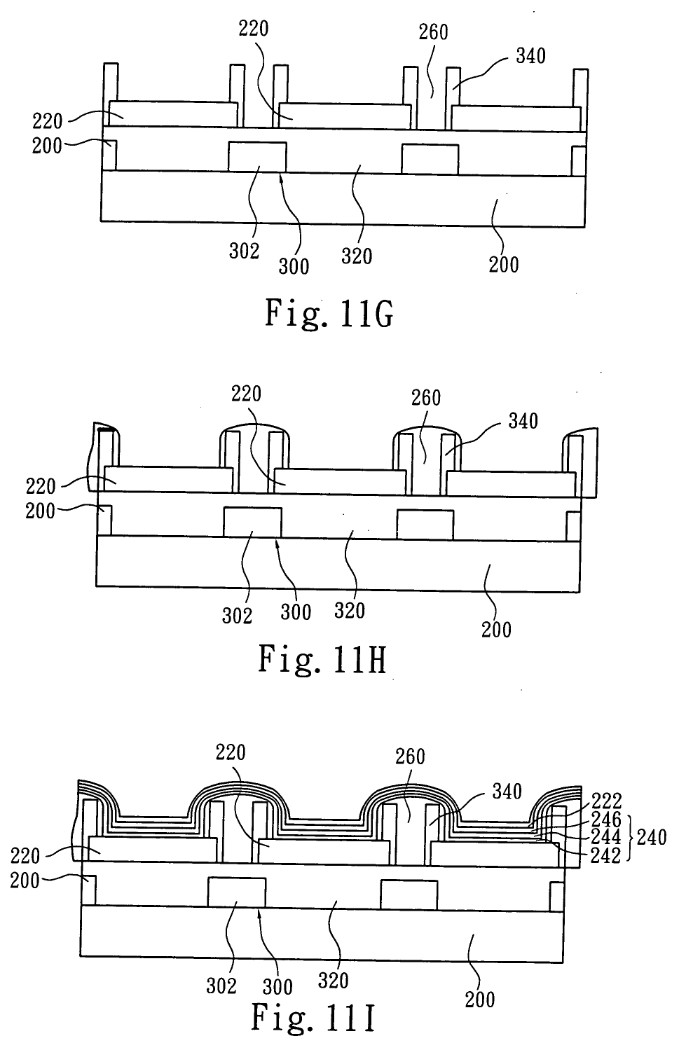

Please refer to FIG. 11A to FIG. 11I, manufacturing flow charts in accordance with a third embodiment of the present invention which comprises the following steps: (a) placing a substrate 200 and using chemical, such as detergent, and deionized water to wash the substrate 200, and then using sputter machine to grow a black matrix film 300, such as chromium oxide; (b) making the black matrix pattern 300 by a lithographic etching process; (c) coating polyimide or acrylic on the structure, and then growing a passivation layer 320, such as silicon oxide or silicon oxide nitride membrane, by a chemical vapor deposit (CVD) process; (d) growing ITO membrane 220 to be an anode on the passivation layer 320; (e) making the anode pattern 220 by a lithographic etching process; 9f) using a sputter or electroplating machine to grow a metallic film 340; (g) making the metallic matrix pattern 340 by a lithographic etching process; (h) coating photoresist material and making an isolation area 260 by lithography process; and (i) growing HTML 242, EML 244, ETL 246, and cathode layer 222, respectively, by a evaporating process.

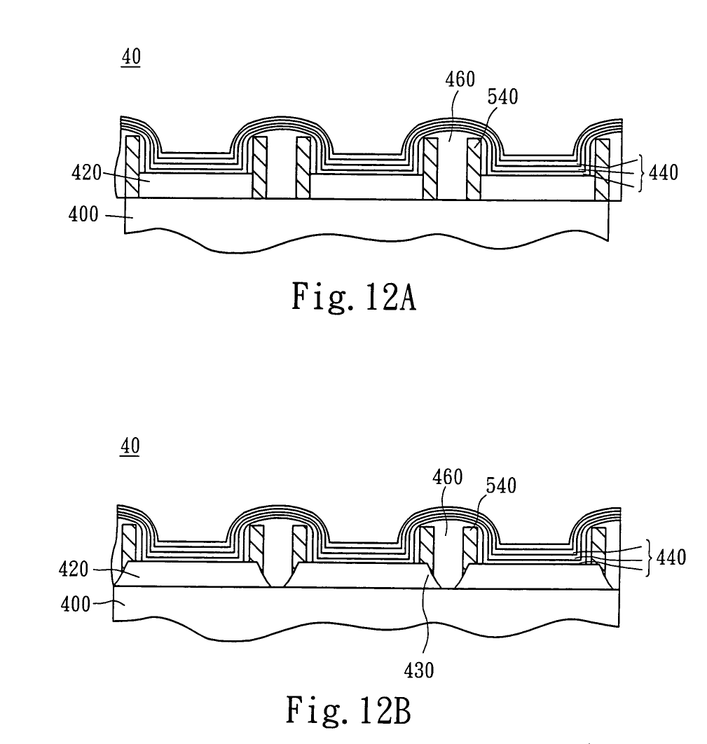

Besides, according to the inventive spirit and technological feature of the present invention, the present invention can also apply in another embodiment, as shown in FIG. 12A and FIG. 12B. The organic light emitting diode element 40 mainly comprises an anode pattern layer 420 with a predetermined pattern deposited on a partial upper surface of a surface 400, a luminescent layer structure 440 deposited on the anode pattern layer 420, an isolation area 460 between the anode pattern layer 420 being an isolation, and a metallic matrix pattern 540 deposited around the anode pattern layer 420. As shown in FIG. 12A, the metallic matrix pattern 540 is at the side edge of the anode pattern layer 420, the metallic matrix pattern 540 is on the edge (not shown) of the anode pattern layer 420, or the metallic matrix pattern 540 is at the side edge of the anode pattern layer 420. The metallic matrix pattern can be made from a material with high conductivity and reflectivity, such as gold, silver, aluminum, copper, and chromium so on.

Further, as shown in FIG. 12B, the anode pattern layer 420 has a tapered lower part 430. Besides, the metallic matrix pattern 540 is at an upper surface of the lower part 430 of the anode pattern layer 420. The metallic matrix pattern can be made from a material with high conductivity and reflectivity, such as gold, silver, aluminum, copper, and chromium so on. Among them, by depositing the metallic matrix pattern 540, not only the reflection interference to the OLED element from external light source can be effectively reduced; furthermore, the visible pixel light emitting area can also be defined. The light emitting mutual interference of different EL colors can be avoided (for example, in full color RGB side by side process, the mutual interference of different colors can be blocked.)

To sum up, the organic light emitting diode element of the present invention has the following advantages:
1. The black matrix pattern can avoid the organic light source from overflowing to the non-display area and reduce external light source reflecting reference to the OLED element to improve the light source color purification and grayscale efficiency and increase distinction of angle of view to improve resolution ability and light emitting efficiency and avoid additional cost of adding polarizer.
2. The black matrix pattern can be used to define display pixel light emitting area of the organic electroluminescent display.

In summary, the present invention can truly achieve expected object and effect. However, the previous disclosed technical means is only a preferred embodiment of the present invention. Any equivalent variations and modifications in process, method, feature, and spirit in accordance with the appended claims may be made without in any way from the scope of the invention.

### LIST OF REFERENCE SYMBOLS

10 prior art organic light emitting diode element
100 substrate
120 anode pattern layer
122 cathode layer
140 luminescent layer structure
142 HTL
144 EML
146 ETL
160 isolation area
20 organic light emitting diode element of the present invention
200 substrate
220 anode pattern layer
222 cathode layer
240 luminescent layer structure
242 HTL
244 EML
246 ETL
260 isolation area
300 black matrix pattern layer
302 first matrix pattern
304 second matrix pattern
320 passivation layer
340 metallic matrix pattern
40 organic light emitting diode element of the present invention
400 substrate
420 anode pattern layer
430 lower part
440 luminescent layer structure
460 isolation area
540 metallic matrix pattern

1. An organic electroluminescent device, comprising:
a substrate;
at least one black matrix pattern layer deposited on said substrate as a predetermined pattern, said black matrix pattern layer having low reflectivity;
a passivation layer laying over said substrate and said black matrix pattern layer;
at least one anode pattern layer deposited on said passivation as a predetermined pattern;
at least one luminescent layer structure deposited on said anode pattern layer; and
at least one isolation area being an isolation between said anode pattern layer;
wherein said black matrix pattern layer has at least one first matrix pattern corresponding to said isolation area.

2. The organic electroluminescent device according to claim 1, wherein said black matrix pattern layer is consisted of one of materials of metallic oxide, polyimide, sensitization acrylate, chromium oxide, non-electrolytic/electroplating nickel and graphite.

3. The organic electroluminescent device according to claim 1, wherein said protection layer can be selectively made from one of materials of resin, epoxy resin, silicon oxide, silicon oxide nitride, polyimide, and acrylic.

4. The organic electroluminescent device according to claim 3, wherein an upper surface of said passivation layer can be selectively grown one of a silicon oxide membrane and silicon oxide nitride film.

5. The organic electroluminescent device according to claim 1, wherein said black matrix pattern layer further comprises at least one second matrix pattern, and said second matrix pattern is deposited a space separated from said first matrix pattern and corresponds to said anode pattern layer.

6. The organic electroluminescent device according to claim 5, wherein said second matrix pattern is selected as one of chunk and at least two partitions.

7. The organic electroluminescent device according to claim 1, wherein circumference of said anode pattern layer is deposited at least one metallic matrix pattern.

8. The organic electroluminescent device according to claim 7, wherein said metallic matrix pattern is selectively deposited one of at the edge, on the top, at side wall of said anode pattern layer, or a combination thereof.

9. The organic electroluminescent device according to claim 7, wherein said black matrix pattern layer and passivation layer is selectively un-deposited, and said anode pattern layer, luminescent layer structure, and isolation area are deposited on said upper surface of said substrate.

10. The organic electroluminescent device according to claim 7, wherein said metallic matrix pattern is selected as a material with high conductivity and high reflectivity.

11. The organic electroluminescent device according to claim 10, wherein said metallic matrix pattern is made from one of material of gold, silver, aluminum, copper, and chromium.

12. The organic electroluminescent device according to claim 1, wherein said luminescent layer structure can be selected as one of capable of radiating monochromatic light source and polychrome light source.

13. A method of manufacturing an organic electroluminescent device, comprises:
(a) placing a substrate and growing a black matrix membrane;
(b) depositing at least one black matrix pattern on an upper surface of said substrate by a lithographic etching process;
(c) growing a passivation layer on said structure;
(d) growing an anode film on said passivation layer;
(e) making at least one anode pattern on an upper surface of said passivation layer by a lithographic etching process;
(f) daubing on an photoresist material and making at least one isolation area by a lithography process; and
(g) depositing at least one luminescent layer structure on a partial upper surface of said anode pattern and isolation area.

14. The manufacturing method according to claim 13, wherein said black matrix pattern layer can be selected as a material of metallic oxide, polyimide, sensitization acrylate, non-electrolytic/electroplating nickel, chromium oxide, and graphite.

15. The manufacturing method according to claim 13, wherein said step (a) comprises growing the chromium oxide film by a sputter machine.

16. The manufacturing method according to claim 13, wherein said passivation layer can be made from one of materials of resin, epoxy resin, silicon oxide, silicon oxide nitride, polyimide, and acrylic.

17. The manufacturing method according to claim 16, wherein an upper surface of said protection layer can be selectively grown one of a silicon oxide film and silicon oxide nitride film.

18. The manufacturing method according to claim 13, wherein said black matrix pattern layer comprises at least one first matrix pattern corresponding to said isolation area and at least one second matrix pattern deposited a space separated from said first matrix pattern, and said second matrix pattern corresponds to said anode pattern layer.

19. The manufacturing method according to claim 18, wherein said second matrix pattern is selected as one of chunk and at least two partitions.

20. The manufacturing method according to claim 13, wherein said luminescent layer structure is selected as one of capable of radiating monochromatic light source and polychrome light source.

21. An organic electroluminescent device, comprising:
a substrate;
at least one anode pattern layer deposited on said substrate as a predetermined pattern;
at least one metallic matrix pattern deposited around said circumference of said anode pattern layer;
at least one luminescent layer structure deposited on said anode pattern layer; and
at least one isolation area being an isolation between said anode pattern layer.

22. The organic electroluminescent device according to claim 21, wherein said metallic matrix pattern is selectively deposited one of at the edge, on the top, at side wall of said anode pattern layer, or a combination thereof.

23. The organic electroluminescent device according to claim 21, wherein said anode pattern layer has a tapered lower part, and said metallic matrix pattern can be deposited on an upper surface of said lower part.

24. The organic electroluminescent device according to claim 21, wherein said metallic matrix pattern is made from a material with high conductivity and reflectivity.
